(19) United States
(12) Patent Application Publication
(10) Pub. No.: US 2011/0253926 A1
(43) Pub. Date: Oct. 20, 2011

(54) Sputtering Target and Method of Forming Film

(75) Inventor: Hiromitsu Hayashi, Omuta-shi (JP)

(73) Assignee: MITSUI MINING & SMELTING CO., LTD., Tokyo (JP)

(21) Appl. No.: 13/141,812

(22) PCT Filed: Dec. 24, 2009
(86) PCT No.: PCT/JP2009/071483

§ 371 Date: Jun. 23, 2011

(30) Foreign Application Priority Data
Dec. 26, 2008 (JP) 2008-333950

(51) Int. Cl. C23C 14/34; H01F 1/04

(52) U.S. Cl. 252/62.55; 204/298.13; 204/192.15

(57) ABSTRACT

Provided is a sputtering target including (Co and Pt) or (Co, Cr, and Pt); SiO₂ and/or TiO₂; and Co₃O₄ and/or CoO. A magnetic recording film having a granular structure and high coercivity can be formed by performing sputtering using the aforementioned sputtering target. By producing the sputtering target by sintering a powder of raw materials at 1000° C. or lower, SiO₂, TiO₂, Co₃O₄, and CoO can be prevented from being reduced during the sintering to give a more effective sputtering target.

### TECHNICAL FIELD

The present invention relates to a sputtering target and a method of forming a film and, more specifically, relates to a sputtering target that can form a magnetic recording film having a granular structure and high coercivity and also relates to a method of forming a film, such as a magnetic recording film, by using the sputtering target.

### BACKGROUND ART

Magnetic recording films constituting, for example, hard disks mounted on computers and so on are usually produced by sputtering using sputtering targets having main components of Co, Cr, and Pt.

The magnetic recording films are required to have high recording densities and low noises. It is known that when the organizational structure of a magnetic recording film is a granular structure, properties of a high recording density and a low noise can be obtained. The term “granular structure” refers to a structure where a non-magnetic material such as an oxide surrounds the periphery of a magnetic crystal grain. In the granular structure, each magnetic crystal grain is almost completely magnetically insulated by the intervention of the non-magnetic material.

In order to obtain a magnetic recording film having such a granular structure by sputtering, an oxide, such as SiO₂ or TiO₂, in addition to Co, Cr, and Pt is blended in the sputtering target. Sputtering using such a sputtering target containing an oxide can give a magnetic recording film having a granular structure composed of magnetic crystal grains of Co, Cr, and Pt deposited in a non-magnetic matrix of, for example, SiO₂ or TiO₂.

However, the use of a sputtering target containing an oxide such as SiO₂ or TiO₂ has a problem of decreasing the coercivity of the obtained magnetic recording film.

As a technology of improving the coercivity of such a magnetic recording film, Japanese Unexamined Patent Application Publication No. 2006-107652 discloses a technology of performing sputtering by introducing argon gas and carbon dioxide with the recognition that the magnetic property (coercivity) is deteriorated by oxidation of the magnetic phase.

Furthermore, Japanese Unexamined Patent Application Publication No. 2006-107625 discloses a magnetic recording medium having reduced magnetic coupling between magnetic grains with the recognition that if the constituent elements of an oxide contaminate the magnetic phase, the perpendicular coercive force (coercivity) is deteriorated.

However, these conventional technologies have not provided sputtering targets that can efficiently form magnetic recording films excellent in coercivity.

### CITATION LIST

### Patent Literature

PTL 1: Japanese Unexamined Patent Application Publication No. 2006-107652
PTL 2: Japanese Unexamined Patent Application Publication No. 2006-107625

### SUMMARY OF INVENTION

### Technical Problem

It is an object of the present invention to provide a sputtering target that can form a magnetic recording film having a granular structure and high coercivity.

### Solution to Problem

The present inventor has predicted that the decreases in coercivity in the above-mentioned magnetic recording films are due to Si or Ti generated by reduction of SiO₂ or TiO₂ during sputtering and has accomplished the present invention under the idea that the decrease in coercivity can be prevented by inhibiting the reduction.

That is, the present invention of achieving the above-mentioned object relates to a sputtering target characterized by containing (Co and Pt) or (Co, Cr, and Pt); SiO₂ and/or TiO₂; and Co₃O₄ and/or CoO.

The sputtering target described above preferably contains Co₃O₄ and/or CoO at a content of 0.1 to 10 mol % and is obtained by sintering, for example, a powder of raw materials including (a Co powder and a Pt powder) or (a Co powder, a Cr powder, and a Pt powder); a SiO₂ powder and/or a TiO₂ powder; and a Co₃O₄ powder and/or a CoO powder. The sintering is preferably performed at 1000° C. or lower.

Furthermore, the sputtering target preferably has a relative density of 94% or more.

Another aspect of the present invention relates to a magnetic recording film obtained by performing sputtering using the above-mentioned sputtering target.

Further another aspect of the present invention relates to a method of forming a magnetic recording film. The method is characterized by performing sputtering using the above-mentioned sputtering target.

### Advantageous Effects of Invention

Sputtering using the sputtering target according to the present invention can form a magnetic recording film having a granular structure and high coercivity. Furthermore, production of the sputtering target according to the present invention by sintering a powder of raw materials at 1000° C. or lower can prevent reduction of oxides, such as SiO₂, TiO₂, Co₃O₄, or CoO, during the sintering to make the sputtering target more effective and is therefore more preferred. In addition, a sputtering target having a relative density of 94% or more can prevent cracking, which is caused by, for example, thermal shock or temperature difference during the sputtering, and also can reduce occurrence of particles and arcing, and is therefore more preferred.

### DESCRIPTION OF EMBODIMENTS

The sputtering target according to the present invention is a sputtering target containing (Co and Pt) or (Co, Cr, and Pt) and SiO₂ and/or TiO₂ and is characterized by further containing Co₃O₄ and/or CoO.

The object of the present invention of obtaining a sputtering target that can form a magnetic recording film having high coercivity is realized by adding an oxide to a common sputtering target containing (Co and Pt) or (Co, Cr, and Pt) and SiO₂ and/or TiO₂, wherein the oxide is that of an element having a standard Gibbs energy change smaller than that in a reaction of Si or Ti contained in the target with one mole of oxygen (O₂) (i.e., the element has a high chemical potential of oxygen for metal/oxide equilibrium).

That is, a sputtering target containing SiO₂ contains an oxide of an element having a standard Gibbs energy change smaller than that in a reaction of Si with one mole of oxygen (O₂); a sputtering target containing TiO₂ contains an oxide of an element having a standard Gibbs energy change smaller than that in a reaction of Ti with one mole of oxygen (O₂); and a sputtering target containing SiO₂ and TiO₂ contains an oxide of an element having a standard Gibbs energy change smaller than that in a reaction of Si with one mole of oxygen (O₂) and also smaller than that in a reaction of Ti with one mole of oxygen (O₂).

The oxide of such an element tends to be reduced more easily than SiO₂ and TiO₂. Therefore, it is conceivable that when the sputtering target containing an oxide of such an element is sputtered, the oxide is reduced earlier than SiO₂ and TiO₂ to inhibit SiO₂ and TiO₂ from being reduced, or the oxide provides oxygen atoms to Si and Ti generated by reduction of SiO₂ and TiO₂ to consequently inhibit SiO₂ and TiO₂ from being reduced, and, as a result, generation of Si and Ti, which causes a decrease in coercivity of a magnetic recording film, is inhibited to prevent a decrease in coercivity of the magnetic recording film.

Examples of the element having a standard Gibbs energy change smaller than that in a reaction of Si or Ti with one mole of oxygen (O₂) include Co, Cr, Pt, B, Sn, Na, Mn, P, Cu, and Fe. Specific examples of the oxides of these elements include Co₃O₄, COO, Cr₂O₃, B₂O₃, SnO₂, Na₂O, and P₂O₅. These oxides may be used alone or in a combination of two or more thereof.

Furthermore, an oxide (e.g., Co₃O₄) having a smaller standard Gibbs energy change is preferred.

Among these oxides, oxides of Co, Cr, and Pt respectively generate Co, Cr, and Pt, which are each an element constituting the magnetic phase of a sputtering target, and do not generate materials that adversely affect sputtering, when the oxides are reduced. Therefore, these oxides are preferred. For example, oxides of Co, such as Co₃O₄ and CoO, and oxides of Cr, such as Cr₂O₃, are preferred.

In addition, an oxide of an element in an oxide state having a higher valence is preferred. Since the amount of oxygen per unit mass of such an oxide is large, oxygen atoms can be efficiently supplied to Si and Ti. From these viewpoints, Co₃O₄ is preferred than CoO as an oxide of Co.

In particular, in the cases of oxides of elements not constituting the magnetic phase of a sputtering target, that is, oxides of elements other than Co, Cr, and Pt, since materials that are foreign matters for the sputtering target are generated when they are reduced, oxides of elements having higher valences can efficiently supply oxygen atoms to Si and Ti in smaller amounts, as described above, and, as a result, the amounts of foreign matters generated are advantageously reduced.

The amount of the oxide such as Co₃O₄ or CoO contained in the sputtering target according to the present invention is preferably 0.1 to 10 mol %, more preferably 0.2 to 3 mol %, more preferably 0.4 to 2 mol %, and most preferably 0.6 to 1.2 mol % based on the total molar number of the components constituting the sputtering target. When the content of the oxide is less than 0.1 mol %, oxygen atoms are not sufficiently supplied to Si and Ti during sputtering, and, thereby, the reduction of SiO₂ and TiO₂ may not be sufficiently reduced. When the content is higher than 10 mol %, a large number of oxide atoms that have not been supplied to Si and Ti during sputtering remain in the target, which may adversely affect the sputtering to reduce the coercivity of the obtained magnetic recording film.

The sputtering target according to the present invention contains (Co and Pt) or (Co, Cr, and Pt) and SiO₂ and/or TiO₂, in addition to the above-mentioned oxide.

(Co and Pt) or (Co, Cr, and Pt) are components constituting the magnetic phase in the target. That is, the target contains Co and Pt as essential components of the magnetic phase and contains Cr as an optional component of the magnetic phase. These compositions may be the same as those in conventional sputtering targets for magnetic recording films. For example, the ratio of Co to the total molar number of Co, Cr, and Pt contained in a target may be 50 to 80 mol %, the ratio of Cr may be 0 to 25 mol %, and the ratio of Pt may be 10 to 25 mol %. Furthermore, the target may contain a component other than Co, Cr, and Pt as a component of the magnetic phase, as long as the object of the present invention can be achieved.

In general, a magnetic film for HDD needs to also be excellent in properties, such as saturation magnetization and squareness ratio, as well as coercivity, and the blending ratios of Co, Cr, Pt, and other components are optimized according to the structures of, for example, a seed layer, a SUL layer, and a cap layer. In the constitution of these structures, an improvement in coercivity is demanded.

SiO₂ and/or TiO₂ are components constituting the non-magnetic phase in the target. That is, the target contains SiO₂, TiO₂, or both SiO₂ and TiO₂ as essential components of the non-magnetic phase. These compositions may be the same as those in conventional sputtering targets for magnetic recording films. For example, on the basis of the total molar number of the components contained in the target, that is, the total molar number of the components constituting the magnetic phase and the non-magnetic phase, the ratio of SiO₂ may be 1 to 15 mol % when only SiO₂ is contained; the ratio of TiO₂ may be 1 to 15 mol % when only TiO₂ is contained; and the total ratio of SiO₂ and TiO₂ may be 1 to 20 mol % when both SiO₂ and TiO₂ are contained. Furthermore, the target may contain a component other than SiO₂ and TiO₂ as a component of the non-magnetic phase, as long as the object of the present invention can be achieved.

The sputtering target according to the present invention preferably has a relative density of 94% or more, more preferably 97% or more. The upper limit of the relative density is not particularly limited, but is usually 100% or less. A target having the above-mentioned relative density, a so-called high-density target, hardly causes cracking due to, for example, thermal shock or temperature difference during the sputtering of the target to allow effective use of the target thickness without loss. In addition, occurrence of particles and arcing can be effectively reduced to also allow an improvement in sputtering rate.

Note that the relative density is a value measured by an Archimedes method for a sputtering target after sintering.

The sputtering target according to the present invention can be produced as in conventional sputtering targets for magnetic recording films. That is, the sputtering target can be produced by mixing (a Co powder and a Pt powder) or (a Co powder, a Cr powder, and a Pt powder); a SiO₂ powder and/or a TiO₂ powder; and a Co₃O₄ powder and/or a CoO powder at a predetermined composition ratio to produce a powder of raw materials and sintering the powder.

The sintering temperature is not particularly limited as long as the object of the present invention can be achieved, but is preferably 1000° C. or less. In sintering at a temperature of higher than 1000° C., oxides such as SiO₂, TiO₂, and Co₃O₄ are reduced during the sintering to cause phenomena such that oxygen atoms generated by the reduction of, for example, Co₃O₄ bind with Cr atoms, which may decrease the performance of the sputtering target.

The method of sintering is not particularly limited, and a hot-press (HP) method, which is conventionally widely employed as a sintering method of a sputtering target, may be used, but it is preferred to use an electric current sintering method.

The sputtering target according to the present invention can be sputtered as in conventional sputtering targets for magnetic recording films.

A magnetic recording film having a granular structure and high coercivity can be formed by performing sputtering using the sputtering target according to the present invention.

### EXAMPLES

### Examples 1 to 31 and 34 to 45, and Comparative Examples 1 to 9

### Production of Sputtering Target

A Co powder having an average particle size of 1.5 μm, a Cr powder having an average particle size of 3.0 μm, a Pt powder having an average particle size of 1.5 μm, a SiO₂ powder having an average particle size of 1.0 μm, a TiO₂ powder having an average particle size of 3.0 μm, a Co₃O₄ powder having an average particle size of 1.0 μm, and a CoO powder having an average particle size of 3 μm were mixed so as to give compositions shown in Table 1 to prepare powder mixtures. The mixing was performed using a ball mill. The composition ratios of Co, Cr, and Pt in Table 1 each mean mol % based on the total molar number of Co, Cr, and Pt constituting the magnetic phase, and the composition ratios of SiO₂, TiO₂, Co₃O₄, and CoO each mean mol % based on the total molar number of all components contained in the powder mixture. Accordingly, when the composition ratio of each component contained in a powder mixture is expressed using mol % based on the total molar number of all components contained in the power mixture, for example, the case of Example 1 can be expressed as “59.735 mol % Co-18.38 mol % Cr-13.785 mol % Pt-4 mol % SiO₂-4 mol % TiO₂-0.1 mol % Co₃O₄”.

The obtained powder mixtures were sintered using an electric current sintering device under the following conditions.

### Sintering Conditions

Sintering atmosphere: vacuum

Temperature rising rate: 800° C./hr

Sintering temperature: shown in Table 1

Sintering holding time: 1 hr

Pressure: 50 MPa

Temperature decreasing rate: 400° C./hr (from the highest sintering temperature to 200° C.)

The resulting sintered compacts were cut to obtain sputtering targets each having a 4 inch diameter (φ).

### Measurement of Relative Density

The relative density of each of the sputtering targets was measured by an Archimedes method. Specifically, the weight-in-air of a sputtering target was divided by the volume (i.e., (weight-in-water of sputtering target sintered compact)/(specific gravity of water at the temperature of measurement)), and a percentage value based on the theoretical density ρ (g/cm³) derived from the following Expression (X) was used as the relative density (unit: %). The results are shown in Table 1.

$$\begin{matrix}[ Expression 1 ] & \\ ρ ≡ {( \frac{{C}_{1} / 100}{{ρ}_{1}} + \frac{{C}_{2} / 100}{{ρ}_{2}} + … + \frac{{C}_{i} / 100}{{ρ}_{i}} )}^{- 1} & ( X )\end{matrix}$$

(In Expression (X), C₁ to Cᵢ show the contents (wt %) of materials constituting a target sintered compact, and ρ₁ to ρᵢ show the densities (g/cm³) of the constitution materials corresponding to C₁ to Cᵢ.)

### Evaluation of Particle Number

Sputtering was conducted using the sputtering target, Co—Zr—Nb for forming a base film, and a Ru target under the film forming conditions shown below.

The number of particles occurred during sputtering was counted and was evaluated based on the criteria shown below. The results are shown in Table 1.

### Film Forming Conditions

Film forming apparatus: single-wafer sputtering apparatus (model: MSL-464, manufactured by Tokki Corp.)

Film structure (thickness): glass substrate/Co—Zr—Nb (20 nm)/Ru (10 nm)/magnetic recording film (15 nm)

Process gas: Ar

Process pressure: 0.2 to 5.0 Pa

Input power: 2.5 to 5.0 W/cm²

Substrate temperature: room temperature to 50° C.

### Evaluation Criteria of Particle Number

◯: satisfactorily usable

Δ: usable

X: not usable

### Measurement of Coercivity of Magnetic Recording Film

Magnetic properties of magnetic recording films produced by sputtering shown in the “evaluation of particle number” were measured with a Kerr effect magnetometer to determine coercivity. The results are shown in Table 1.

### Examples 32 and 33

Sputtering targets were obtained as in Example 1 except that a hot-press sintering device was used instead of the electric current sintering device.

These sputtering targets were subjected to measurement of relative density, evaluation of particle number, and measurement of coercivity, as in Example 1. The results are shown in Table 1.

TABLE 1

| | Magnetic | | | Non-magnetic | | | | Sintering | | Relative | |
|---|---|---|---|---|---|---|---|---|---|---|---|
| | phase | | | phase | | Oxide | | temperature | | density | Particle |
| | Co | Cr | Pt | SiO₂ | TiO₂ | Co₃O₄ | CoO | (° C.) | Coercivity | (%) | number |
| Comparative | 65 | 20 | 15 | 4 | 4 | 0 | 0 | 930 | 5.10 | 97.1 | ◯ |
| Example 1 | | | | | | | | | | | |
| Example 1 | 65 | 20 | 15 | 4 | 4 | 0.1 | 0 | 930 | 5.25 | 97.1 | ◯ |
| Example 2 | 65 | 20 | 15 | 4 | 4 | 0.2 | 0 | 930 | 5.31 | 97.6 | ◯ |
| Example 3 | 65 | 20 | 15 | 4 | 4 | 0.4 | 0 | 930 | 5.36 | 98.3 | ◯ |
| Example 4 | 65 | 20 | 15 | 4 | 4 | 0.6 | 0 | 930 | 5.40 | 98.7 | ◯ |
| Example 5 | 65 | 20 | 15 | 4 | 4 | 1.0 | 0 | 930 | 5.46 | 98.5 | ◯ |
| Example 6 | 65 | 20 | 15 | 4 | 4 | 1.2 | 0 | 930 | 5.42 | 98.4 | ◯ |
| Example 7 | 65 | 20 | 15 | 4 | 4 | 1.4 | 0 | 930 | 5.37 | 98.3 | ◯ |
| Example 8 | 65 | 20 | 15 | 4 | 4 | 1.6 | 0 | 930 | 5.36 | 97.8 | ◯ |
| Example 9 | 65 | 20 | 15 | 4 | 4 | 2.0 | 0 | 930 | 5.35 | 97.5 | ◯ |
| Example 10 | 65 | 20 | 15 | 4 | 4 | 2.2 | 0 | 930 | 5.34 | 97.3 | ◯ |
| Example 11 | 65 | 20 | 15 | 4 | 4 | 2.5 | 0 | 930 | 5.32 | 97.4 | ◯ |
| Example 12 | 65 | 20 | 15 | 4 | 4 | 3.0 | 0 | 930 | 5.31 | 97.5 | ◯ |
| Example 13 | 65 | 20 | 15 | 4 | 4 | 3.5 | 0 | 930 | 5.29 | 97.4 | ◯ |
| Example 14 | 65 | 20 | 15 | 4 | 4 | 4.0 | 0 | 930 | 5.27 | 97.3 | ◯ |
| Example 15 | 65 | 20 | 15 | 4 | 4 | 4.5 | 0 | 930 | 5.24 | 97.5 | ◯ |
| Example 16 | 65 | 20 | 15 | 4 | 4 | 5.0 | 0 | 930 | 5.21 | 97.4 | ◯ |
| Example 17 | 65 | 20 | 15 | 4 | 4 | 5.5 | 0 | 930 | 5.19 | 97.3 | ◯ |
| Example 18 | 65 | 20 | 15 | 4 | 4 | 1.0 | 0 | 980 | 5.43 | 98.8 | ◯ |
| Example 19 | 65 | 20 | 15 | 4 | 4 | 1.0 | 0 | 930 | 5.46 | 98.5 | ◯ |
| Example 20 | 65 | 20 | 15 | 4 | 4 | 1.0 | 0 | 880 | 5.48 | 95.1 | Δ |
| Example 21 | 65 | 20 | 15 | 4 | 4 | 1.0 | 0 | 850 | 5.48 | 94.5 | Δ |
| Example 22 | 65 | 20 | 15 | 4 | 4 | 0 | 1.0 | 930 | 5.23 | 98.3 | ◯ |
| Example 23 | 65 | 20 | 15 | 4 | 4 | 0 | 2.0 | 930 | 5.25 | 98.0 | ◯ |
| Example 24 | 65 | 20 | 15 | 4 | 4 | 0 | 3.0 | 930 | 5.28 | 98.5 | ◯ |
| Example 25 | 65 | 20 | 15 | 4 | 4 | 0 | 4.0 | 930 | 5.29 | 98.4 | ◯ |
| Example 26 | 65 | 20 | 15 | 4 | 4 | 0 | 5.0 | 930 | 5.24 | 98.1 | ◯ |
| Example 27 | 65 | 20 | 15 | 4 | 4 | 0 | 6.0 | 930 | 5.18 | 98.1 | ◯ |
| Comparative | 65 | 20 | 15 | 5 | 0 | 0 | 0 | 930 | 4.98 | 99.1 | ◯ |
| Example 2 | | | | | | | | | | | |
| Example 28 | 65 | 20 | 15 | 5 | 0 | 0 | 4.0 | 930 | 5.09 | 98.5 | ◯ |
| Example 29 | 65 | 20 | 15 | 5 | 0 | 1.0 | 0 | 930 | 5.26 | 98.8 | ◯ |
| Comparative | 65 | 20 | 15 | 1 | 5 | 0 | 0 | 930 | 4.93 | 97.8 | ◯ |
| Example 3 | | | | | | | | | | | |
| Example 30 | 65 | 20 | 15 | 1 | 5 | 0 | 4.0 | 930 | 5.05 | 97.6 | ◯ |
| Example 31 | 65 | 20 | 15 | 1 | 5 | 1.0 | 0 | 930 | 5.22 | 98.0 | ◯ |
| Example 32 | 65 | 20 | 15 | 4 | 4 | 1.0 | 0 | 1230 | 5.35 | 98.3 | ◯ |
| Example 33 | 65 | 20 | 15 | 4 | 4 | 1.0 | 0 | 1100 | 5.36 | 95.3 | Δ |
| Comparative | 50 | 25 | 25 | 10 | 2 | 0 | 0 | 930 | 4.24 | — | — |
| Example 4 | | | | | | | | | | | |
| Example 34 | 50 | 25 | 25 | 10 | 2 | 0 | 4.0 | 930 | 4.29 | — | — |
| Example 35 | 50 | 25 | 25 | 10 | 2 | 1.0 | 0 | 930 | 4.35 | — | — |
| Comparative | 50 | 25 | 25 | 6 | 0 | 0 | 0 | 930 | 5.10 | — | — |
| Example 5 | | | | | | | | | | | |
| Example 36 | 50 | 25 | 25 | 6 | 0 | 0 | 4.0 | 930 | 5.15 | — | — |
| Example 37 | 50 | 25 | 25 | 6 | 0 | 1.0 | 0 | 930 | 5.21 | — | — |
| Comparative | 80 | 10 | 10 | 0 | 10 | 0 | 0 | 930 | 5.18 | — | — |
| Example 6 | | | | | | | | | | | |
| Example 38 | 80 | 10 | 10 | 0 | 10 | 0 | 4.0 | 930 | 5.29 | — | — |
| Example 39 | 80 | 10 | 10 | 0 | 10 | 1.0 | 0 | 930 | 5.48 | — | — |
| Comparative | 70 | 10 | 20 | 8 | 7 | 0 | 0 | 930 | 5.01 | — | — |
| Example 7 | | | | | | | | | | | |
| Example 40 | 70 | 10 | 20 | 8 | 7 | 0 | 4.0 | 930 | 5.25 | — | — |
| Example 41 | 70 | 10 | 20 | 8 | 7 | 1.0 | 0 | 930 | 5.34 | — | — |
| Comparative | 85 | 5 | 10 | 3 | 1 | 0 | 0 | 930 | 5.15 | — | — |
| Example 8 | | | | | | | | | | | |
| Example 42 | 85 | 5 | 10 | 3 | 1 | 0 | 4.0 | 930 | 5.27 | — | — |
| Example 43 | 85 | 5 | 10 | 3 | 1 | 1.0 | 0 | 930 | 5.38 | — | — |
| Comparative | 80 | 0 | 20 | 6 | 3 | 0 | 0 | 930 | 5.18 | — | — |
| Example 9 | | | | | | | | | | | |
| Example 44 | 80 | 0 | 20 | 6 | 3 | 0 | 4.0 | 930 | 5.28 | — | — |
| Example 45 | 80 | 0 | 20 | 6 | 3 | 1.0 | 0 | 930 | 5.47 | — | — |

1. A sputtering target comprising (Co and Pt) or (Co, Cr, and Pt); SiO₂ and/or TiO₂; and Co₃O₄ and/or CoO.

2. The sputtering target according to claim 1, wherein the content of Co₃O₄ and/or CoO is 0.1 to 10 mol %.

3. The sputtering target according to claim 1, wherein the target is obtained by sintering a powder of raw materials at 1000° C. or lower.

4. The sputtering target according to claim 1, wherein the target has a relative density of 94% or more.

5. A magnetic recording film formed by conducting sputtering using the sputtering target according to claim 1.

6. A method of forming a magnetic recording film, the method comprising conducting sputtering using the sputtering target according to claim 1.

7. The sputtering target according to claim 2, wherein the target is obtained by sintering a powder of raw materials at 1000° C. or lower.

8. The sputtering target according to claim 2, wherein the target has a relative density of 94% or more.

9. The sputtering target according to claim 3, wherein the target has a relative density of 94% or more.

10. A magnetic recording film formed by conducting sputtering using the sputtering target according to claim 2.

11. A magnetic recording film formed by conducting sputtering using the sputtering target according to claim 3.

12. A magnetic recording film formed by conducting sputtering using the sputtering target according to claim 4.

13. A method of forming a magnetic recording film, the method comprising conducting sputtering using the sputtering target according to claim 2.

14. A method of forming a magnetic recording film, the method comprising conducting sputtering using the sputtering target according to claim 3.

15. A method of forming a magnetic recording film, the method comprising conducting sputtering using the sputtering target according to claim 4.
